(19) United States
(12) Patent Application Publication
(10) Pub. No.: US 2012/0155146 A1
(43) Pub. Date: Jun. 21, 2012

(54) RESISTANCE-CHANGE MEMORY

(76) Inventors: Yoshihiro UEDA, Yokohama-shi (JP); Kenji Tsuchida, Kawasaki-shi (JP)

(21) Appl. No.: 13/331,229

(22) Filed: Dec. 20, 2011

(30) Foreign Application Priority Data
Dec. 20, 2010 (JP) 2010-283204

(51) Int. Cl. G11C 11/00

(52) U.S. Cl. 365/148

(57) ABSTRACT

According to one embodiment, a resistance-change memory includes memory cells between a bit line and a source line, each of the memory cells including a memory element and a cell transistor having a gate connected to a word line, an n-channel transistor having a gate to which a first control voltage is applied, and a current path connected to the bit line, and a p-channel transistor having a gate to which a second control voltage is applied, and a current path connected to the source line. When the memory cell is read, the potential of the bit line is controlled by the first control voltage, and the potential of the source line is controlled by the second control voltage.

### CROSS-REFERENCE TO RELATED APPLICATIONS

This application is based upon and claims the benefit of priority from prior Japanese Patent Application No. 2010-283204, filed Dec. 20, 2010, the entire contents of which are incorporated herein by reference.

### FIELD

Embodiments described herein relate generally to a resistance-change memory.

### BACKGROUND

Recently, as next-generation semiconductor memories, resistance-change memories such as magnetoresistive RAM (MRAM), resistive RAM (ReRAM), and phase-change RAM (PCRAM) have been attracting attention.

In a cell array of the resistance-change memory, memory cells are two-dimensionally arranged. The memory cells are connected to the same interconnect and circuit.

For example, in a read, a memory cell selected as a read target is connected to the same interconnect and circuit as unselected memory cells.

Therefore, the unselected memory cells may affect the operation of the selected memory cell.

### BRIEF DESCRIPTION OF THE DRAWINGS

FIG. 1 is a diagram showing the basic configuration of a resistance-change memory according to embodiments;

FIG. 2 is a diagram explaining the circuit configuration of a resistance-change memory according to the first embodiment;

FIG. 3 is a diagram explaining the internal configuration of a cell array;

FIG. 4 is a diagram showing the structure of a resistance-change memory element;

FIG. 5 is a diagram showing the structure of the resistance-change memory element;

FIG. 6 is a diagram explaining the circuit configuration of the resistance-change memory according to the first embodiment;

FIG. 7 is a diagram explaining the circuit configuration of a resistance-change memory according to the second embodiment;

FIG. 8 is a diagram explaining the circuit configuration of the resistance-change memory according to the second embodiment;

FIG. 9 is a diagram showing the structure of a resistance-change memory element; and

FIG. 10 is a diagram showing the structure of the resistance-change memory element.

### DETAILED DESCRIPTION

### Embodiments

Hereinafter, embodiments will be described in detail with reference to the drawings. In the following explanation, elements having the same function and configuration are provided with the same signs and are repeatedly described when necessary.

In general, according to one embodiment, a resistance-change memory includes a bit line; a source line; word lines; memory cells connected between the bit line and the source line, each of the memory cells including a memory element in which a resistance is correlated with data to be stored, and a first cell transistor having a gate connected to the word line; an n-channel first transistor, the first transistor having a first gate to which a first control voltage is applied, and a first current path connected to the bit line; and a p-channel second transistor, the second transistor having a second gate to which a second control voltage is applied, and a second current path connected to the source line. When a selected memory cell is read, the potential of the bit line is controlled by the first control voltage, and the potential of the source line is controlled by the second control voltage.

### (1) Basic Configuration

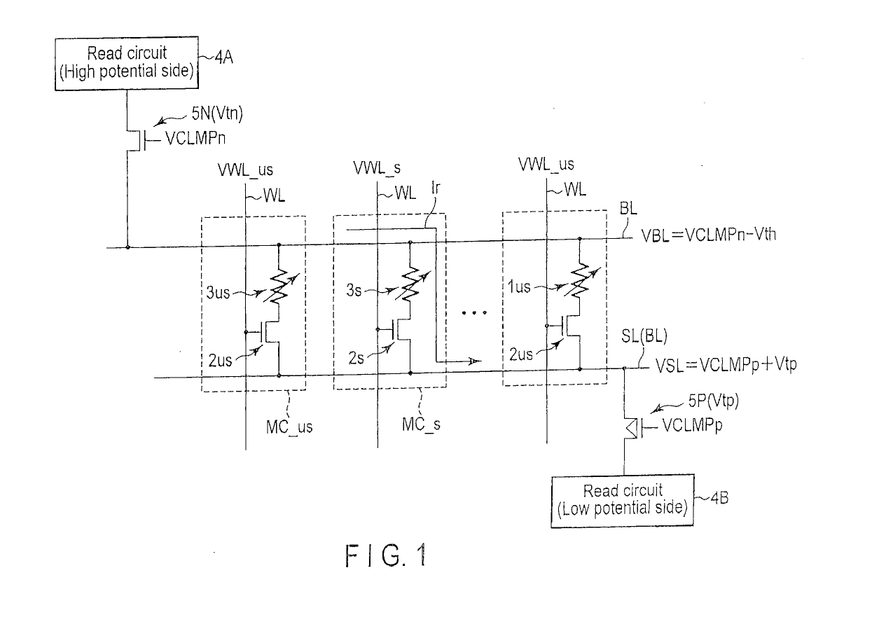

The basic configuration of a resistance-change memory according to the embodiments is described with reference to FIG. 1.

FIG. 1 shows the connection of components in the resistance-change memory according to the embodiments during a read operation.

As shown in FIG. 1, memory cells MC_s and MC_us are connected between a bit line (first interconnect, control line) BL and a source line (second interconnect, control line) SL. Memory cells MC_s and MC_us are hereinafter simply referred to as a memory cell MC when not distinguished from each other. Although the interconnect that pairs with the bit line BL is referred to as the source line for a clear explanation in the embodiments, this source line may also be referred to as a bit line. In the embodiments, the source line is an interconnect (bit line) to be on a low potential side when the memory cell is read.

Each of memory cells MC_s and MC_us includes a resistance-change memory element 3s or 3us, and a field-effect transistor 2s or 2us as a selective element. The resistance-change memory elements 3s and 3us are hereinafter simply referred to as a resistance-change memory element 3 when not distinguished from each other. Field-effect transistors 2s and 2us are hereinafter simply referred to as a field-effect transistor 2 when not distinguished from each other.

One end of the resistance-change memory element 3 is connected to the bit line BL. The other end of the resistance-change memory element 3 is connected to one end of the current path of field-effect transistor 2. The other end of field-effect transistor 2 is connected to the source line SL. The gates of field-effect transistors 2 are connected to word lines (control lines) WL, respectively. Field-effect transistor 2 in the memory cell MC is hereinafter referred to as a cell transistor 2.

The resistance-change memory element 3 changes in resistance with the polarity, magnitude, or supply period of a supplied current/voltage. The variable resistance state is correlated with data to be stored such that the data is stored in the resistance-change memory element 3.

The on/off of cell transistor 2 is controlled to change the connection between the memory cell MC and the bit line BL/source line SL. Cell transistor 2 is, for example, an n-channel field-effect transistor.

Read circuits 4A and 4B are connected to the bit line BL and the source line SL, respectively. Each of read circuits 4A and 4B includes a sense amplifier, a source/sink circuit (constant current source or constant voltage source) for generating a read current, and a source/sink circuit for generating a standard current.

When the memory cell is read, for example, read circuit 4A is on the high potential side relative to the memory cell MC, and read circuit 4B is on the low potential side relative to the memory cell MC.

High-potential-side read circuit 4A is connected to the bit line BL via a field-effect transistor 5N. Low-potential-side read circuit 4B is connected to the source line SL via a field-effect transistor 5P.

One end the current path of field-effect transistor 5N is connected to the bit line BL. The other end of the current path of field-effect transistor 5N is connected to read circuit 4A. When field-effect transistor 5N is driven, a control voltage VCLMPn (V1) is applied to the gate of field-effect transistor 5N.

One end the current path of field-effect transistor 5P is connected to the source line SL. The other end of the current path of field-effect transistor 5P is connected to read circuit 4B. When field-effect transistor 5P is driven, a control voltage VCLMPp (V2) is applied to the gate of field-effect transistor 5P.

Field-effect transistor 5N is an n-channel field-effect transistor 5N. Field-effect transistor 5P is a p-channel field-effect transistor 5P. Here, the threshold voltage of n-channel field-effect transistor 5N is referred to as Vtn, and the threshold voltage of p-channel field-effect transistor 5P is referred to as Vpn. Field-effect transistors 5N and 5P act as source followers.

During the read operation of the resistance-change memory, a select potential VWL_s is applied to the word line WL connected to a selected memory cell (here, memory cell MC_s), and field-effect transistor 2s in the selected cell MC_s is switched on. In the meantime, an unselect potential VWL_us is applied to the word lines WL connected to the unselected memory cells MC_us. The unselect potential VWL_us is a potential that does not switch on field-effect transistors 2us in the unselected memory cells MC_us, and is, for example, zero. Hereinafter, the word line to which the selected cell is connected is referred to as a selected word line, and the word line to which the unselected cell is connected is referred to as an unselected word line. The select potential VWL_s applied to the selected word line is referred to as a selected word line potential VWL_s, and the unselect potential VWL_us applied to the unselected word lines is referred to as an unselected word line potential VWL_us.

By the application of control potentials VCLMPn and VCLMPp, field-effect transistors 5N and 5P are switched on, and read circuits 4A and 4B are electrically connected to the selected cell MC_s via the bit line BL and the source line SL.

Further, n-channel field-effect transistor 5N uses control potential VCLMPn to clamp the potential of the bit line BL to a predetermined potential VBL, and p-channel field-effect transistor 5P uses control potential VCLMPp to clamp the potential of the source line SL to a predetermined potential VSL.

During the read operation, the potential (hereinafter referred to as a bit line potential) VBL of the bit line BL is controlled to be approximately equal to VCLMPp−Vtn, and the potential (hereinafter referred to as a source line potential) VSL of the source line SL is controlled to be approximately equal to VCLMPp+Vtp. The bit line potential VBL (=VCLMPn−Vtn) is higher than the source line potential VSL (=VCLMPp+Vtp).

The selected word line potential VWL_s is higher than the bit line potential VBL and the source line potential VSL. The unselected word line potential VWL_us is lower than the bit line potential VBL and the source line potential VSL.

Thus, a read current Ir flows to low-potential-side read circuit 4B from high-potential-side read circuit 4A via the selected cell MC_s. Read circuits (e.g., sense amplifiers) 4A and 4B compare, for example, a standard current (or a standard voltage) with the read current (or a potential variation resulting from the read current), and detects the resistance of the resistance-change memory element 3s in the selected cell MC_s. As a result, data corresponding to the resistance of the resistance-change memory element 3s is read in the selected cell MC_s. For example, an output current of the constant current source or the constant voltage source (not shown) provided in read circuit 4A or 4B is directly supplied to the sense amplifier in read circuit 4A or 4B as a standard current (standard voltage).

Here, an unselected word line potential VWL_us of zero is applied to the gate of field-effect transistor 2us of the unselected cell MC_us, and the source line potential VSL is applied to the source of transistor 2us.

Therefore, a source voltage of cell transistor 2us is higher than a gate voltage of cell transistor 2us. In n-channel cell transistor 2us of the unselected cell MC_us, a reverse bias is applied to an n-channel diffusion layer as a source and to a p-channel semiconductor region as a channel region.

In the resistance-change memory according to the embodiments, a leakage current from cell transistor 2us in the unselected cell MC_us is inhibited by the above-described relation of the potential across the gate and source of cell transistor 2us in the unselected cell MC_us.

As described above, in the resistance-change memory according to the embodiments, in the path where the read current flows, n-channel field-effect transistor which clamps the potential of the high-potential-side interconnect is connected to the bit line to which the memory cells are connected, and the p-channel field-effect transistor which clamps the potential of the low-potential-side interconnect is connected to the sourcen line that pairs with the bit line. Moreover, the potential of the source line is set to be higher than the potential of the word line to which the unselected memory cell is connected.

Consequently, the resistance-change memory according to the embodiments enables improved read accuracy.

### (2) First Embodiment

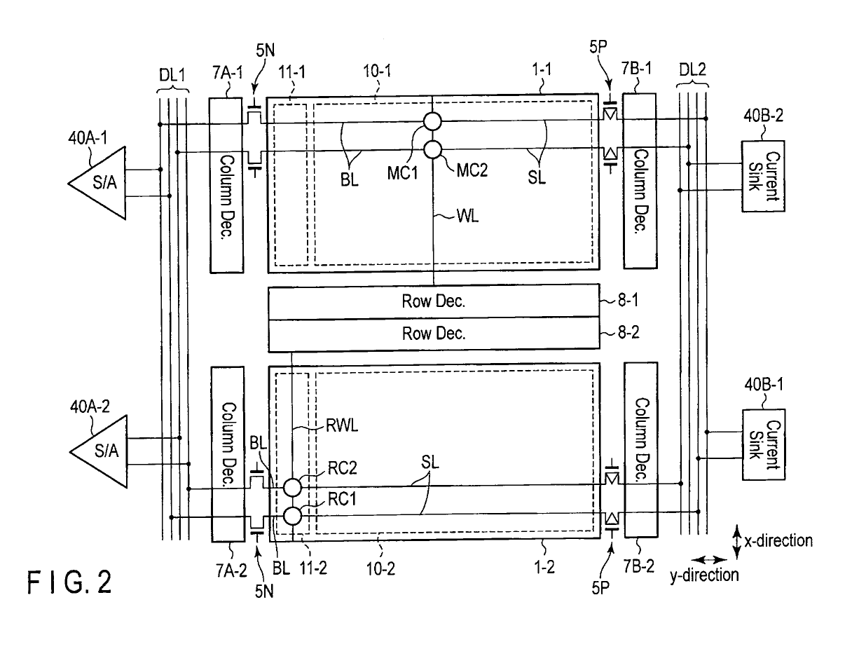

A resistance-change memory according to the first embodiment is described with reference to FIG. 2 to FIG. 6.

(a) Circuit Configuration

The circuit configuration of the resistance-change memory according to the first embodiment is described with reference to FIG. 2 to FIG. 6.

FIG. 2 is a block diagram showing a configuration example of the resistance-change memory according to the first embodiment. In the present embodiment, a magnetoresistive RAM (MRAM) is shown as an example of the resistance-change memory.

As shown in FIG. 2, the MRAM according to the present embodiment includes, for example, two cell arrays 1-1 and 1-2. The MRAM according to the present embodiment also includes read circuits. Cell arrays 1-1 and 1-2 are connected to the read circuits.

In the present embodiment, each of the read circuits is formed of one sense amplifier 40A-1 or 40A-2 and one sink circuit (e.g., current sink) 40B-1 or 40B-2.

The two cell arrays 1-1 and 1-2 are adjacent to each other in an x-direction.

Two row decoders 8-1 and 8-2 are provided between the two cell arrays 1-1 and 1-2. Cell array 1-1 is connected to the row decoder 8-1, and cell array 1-2 is connected to the row decoder 8-2.

Column decoders 7A-1, 7B-1, 7A-2, and 7B-2 are provided at both ends of cell arrays 1-1 and 1-2 in a y-direction, respectively.

Column decoder 7B-1 is connected to cell array 1-1 on the side of sense amplifier 40A-1. Column decoder 7A-1 is connected to cell array 1-1 on the side of current sink 40B-1.

Column decoder 7B-2 is connected to cell array 1-2 on the side of sense amplifier 40A-2. Column decoder 7A-2 is connected to cell array 1-2 on the side of current sink 40B-2.

Memory cell regions 10-1 and 10-2 and reference cell regions 11-1 and 11-2 are provided in cell arrays 1-1 and 1-2, respectively.

Memory cells are arranged in matrix form in each of the memory cell regions 10-1 and 10-2. Reference cells RC are arranged in each of the reference cell regions 11-1 and 11-2.

The two sense amplifiers 40A-1 and 40A-2 are provided for the two cell arrays 1-1 and 1-2.

Each of sense amplifiers 40A-1 and 40A-2 has two input terminals. Each of the input terminals of sense amplifiers 40A-1 and 40A-2 is connected to one of four data lines DL1.

One of the input terminals of sense amplifier 40A-1 is connected to cell array 1-1 via one data line DL1, and the other input terminal of sense amplifier 40A-1 is connected to cell array 1-2 via one data line DL1. One of the input terminals of sense amplifier 40A-2 is connected to cell array 1-1 via one data line DL1, and the other input terminal of sense amplifier 40A-2 is connected to cell array 1-2 via one data line DL1.

The two cell current sinks (sink circuits) 40B-1 and 40B-2 are provided for the two cell arrays 1-1 and 1-2.

Each of current sinks 40B-1 and 40B-2 has two input terminals. Each of the input terminals of current sinks 40B-1 and 40B-2 is connected to one of four data lines DL2.

One of the input terminals of current sink 40B-1 is connected to cell array 1-1 via one data line DL2, and the other input terminal of current sink 40B-1 is connected to cell array 1-2 via one data line DL2. One of the input terminals of current sink 40B-2 is connected to cell array 1-1 via one data line DL2, and the other input terminal of current sink 40B-2 is connected to cell array 1-2 via one data line DL2.

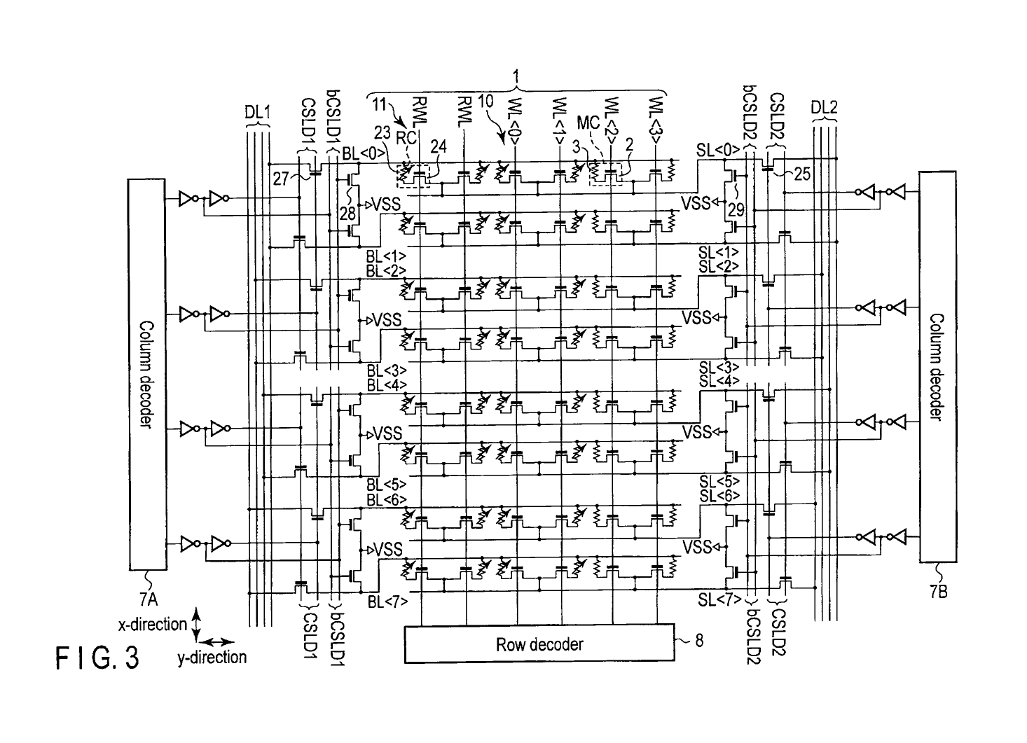

FIG. 3 is a circuit diagram showing the configurations of one cell array 1 and its peripheral circuits.

Each of cell arrays 1-1 and 1-2 in FIG. 2 has, for example, the configuration shown in FIG. 3. Bit lines BL extending in a y-direction (column direction), source lines SL extending in the y-direction, word lines WL extending in an x-direction (row direction), and reference word lines RWL extending in the x-direction are provided in the cell array 1.

Although eight bit lines BL<0> to BL<7>, eight source lines SL<0> to SL<7>, four word lines WL<0> to WL<3>, and two reference word lines RWL<0> and RWL<1> are illustrated in FIG. 3, these lines are not limited to the above-mentioned numbers.

As described above, a memory cell region 11 and a reference cell region 12 are provided in the cell array 1. Memory cells MC are arranged in matrix form in the memory cell region 11. The reference cells RC are arranged in the reference cell region 12.

The memory cell MC includes one resistance-change memory element 3 and at least one cell transistor 2. For example, an n-channel metal oxide semiconductor (MOS) transistor is used as cell transistor 2. One end of the resistance-change memory element 3 is connected to the bit line BL<m>, and the other end of the resistance-change memory element 3 is connected to one end of the current path of cell transistor 2. The other end of the current path of cell transistor 2 is connected to the source line SL<m>, and the gate of cell transistor 2 is connected to the word line WL<n>, where m is any one of integers 0 to 7 and n is any one of integers 0 to 3.

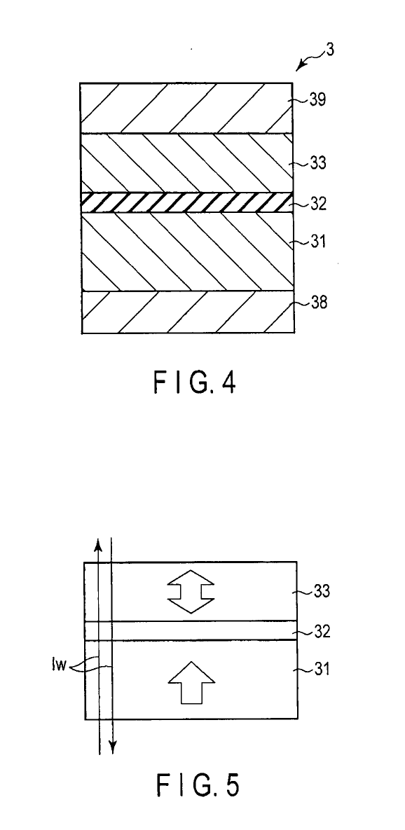

For example, a magnetoresistive-effect element (e.g., MTJ element) is used as the resistance-change memory element 3. FIG. 4 is a sectional view showing the configuration of the MTJ element 3. The MTJ element 3 is formed of a lower electrode 38, a reference layer (also referred to as a fixed layer, pin layer, or pined layer) 31, a nonmagnetic layer (also referred to as a tunnel barrier layer) 32, a recording layer (also referred to as storage layer or a free layer) 33, and an upper electrode 39 that are stacked. The layers may be stacked in reverse order.

The reference layer 31 and the recording layer 33 are each made of a ferromagnetic material. The reference layer 31 and the recording layer 33 have magnetic anisotropy in a direction perpendicular to a film plane, and the easy magnetization directions thereof are perpendicular to the film plane. The magnetization directions of the reference layer 31 and the recording layer 33 may be parallel to the film plane.

The reference layer 31 is invariable (fixed) in the direction of its magnetization (or spin). The recording layer 33 is variable (inverted) in the direction of its magnetization (or spin).

The reference layer 31 is formed to have perpendicular magnetic anisotropy energy sufficiently higher than that of the recording layer 33. The magnetic anisotropies of the magnetic layers 31 and 33 can be set by adjusting the material constitution and thickness thereof. In the MTJ element 3, the magnetization inversion threshold of the recording layer 33 is low, and the magnetization inversion threshold of the reference layer 31 is higher than the magnetization inversion threshold of the recording layer 33. Thus, the MTJ element 3 having the reference layer 31 invariable in magnetization direction and the recording layer 33 variable in magnetization direction can be formed.

FIG. 5 is a schematic diagram explaining the magnetization of the MTJ element 3. In the present embodiment, a spin-torque-transfer write method is used to pass a write current Iw through the MTJ element 3 and control the magnetization of the MTJ element 3 by the write current Iw. The write current Iw is controlled so that the it is greater than or equal to the magnetization inversion threshold of the recording layer 33 and is less than the magnetization inversion threshold of the reference layer 31.

The MTJ element 3 can take one of two states including a high-resistance state and a low-resistance state, depending on whether the magnetizations of the reference layer 31 and the recording layer 33 are parallel or antiparallel to each other.

As shown in FIG. 5, if the write current Iw flowing from the recording layer 33 to the reference layer 31 is passed through the MTJ element 3 in which the magnetizations are arranged antiparallel to each other, electrons having a spin in the same direction as the magnetization arrangement of the reference layer 31 predominate as electrons supplied to the recording layer 33 via the nonmagnetic layer 32.

The magnetization direction of the recording layer 33 is changed (inverted) to the same direction as the magnetization direction of the reference layer 31 by the spin torque of the electrons which have passed (tunneled) through the nonmagnetic layer 32. As a result, the magnetizations of the reference layer 31 and the recording layer 33 become parallel.

When the magnetizations of the reference layer 31 and the recording layer 33 are arranged parallel to each other, the resistance of the MTJ element 3 is minimized, that is, the MTJ element 3 is in the low-resistance state. The low-resistance state of the MTJ element 3 is set to, for example, binary 0.

If the write current Iw flowing from the reference layer 31 to the recording layer 33 is passed through the MTJ element 3 in which the magnetizations are arranged parallel, electrons having a spin in the same direction as the magnetization arrangement of the reference layer 31 and the magnetization arrangement of the recording layer 33 before inverted in magnetization move to the reference layer 31 via the nonmagnetic layer 32. In the meantime, electrons having a spin in a direction opposite to the magnetization arrangement of the reference layer 31 are reflected by the nonmagnetic layer 32 or the reference layer 31. The magnetization direction of the recording layer 33 is changed to a direction opposite to the magnetization arrangement of the reference layer 31 by the spin torque of the reflected electrons. As a result, the magnetizations of the recording layer 33 and the reference layer 31 become antiparallel to each other.

When the magnetizations of the reference layer 31 and the recording layer 33 are arranged antiparallel to each other, the resistance of the MTJ element 3 is maximized, that is, the MTJ element 3 is in the high-resistance state. The high-resistance state of the MTJ element 3 is set to, for example, binary 1.

Consequently, the MTJ element 3 is used as a storage element capable of storing one-bit data (binary data). The write current Iw is supplied to the MTJ element 3 in a selected cell so that the write current Iw flows from the bit line side to the source line side via the selected cell or from the source line side to the bit line side via the selected cell depending on data to be written. The write current Iw is generated by a write circuit (not shown) having a current source or a voltage source.

The reference cell RC has, for example, the same circuit configuration as the memory cell MC, and includes one resistive element 23 and one cell transistor 24. One end of the resistive element 23 is connected to the bit line BL<m>, and the other end of the resistive element 23 is connected to one end of the current path of cell transistor 24. The other end of the current path of cell transistor 24 is connected to the source line SL<m>. The gate of cell transistor 24 is connected to the reference word line RWL. Thus, the reference cell RC is connected to the same bit line BL<m> and source line SL<m> as the memory cell MC.

When the selected cell is read, the resistive element 23 is used to generate a reference current serving as the standard for determining the data in the memory cell MC. The resistance of the resistive element 23 is fixed. The resistive element 23 has, for example, a stack structure similar to that of the MTJ element 3. The resistive element (MTJ element) 23 of the reference cell RC is not selected as a write target, and its action on the reference cell RC is controlled to prevent the resistance from changing. The magnetization of the recording layer 33 of the resistive element 23 of the reference cell RC may be fixed as in the reference layer 31.

Each bit line BL<m> is connected to one of the four data lines DL1 via a column select transistor 27. Column select transistor 27 is, for example, an n-channel MOS transistor. The gate of column select transistor 27 is connected to a column select line CSLD1.

Column decoder 7A is connected to column select line CSLD1 via a buffer (two inverters). Column decoder 7A controls the on/off of a column select transistor 28 via column select line CSLD1. When column select transistor 27 is switched on, a selected bit line BL<m> is connected to data line DL1.

Field-effect transistor 28 is connected to each bit line BL<m>. The transistor 28 is, for example, an n-channel MOS transistor. The drain of field-effect transistor 28 is connected to the bit line BL<m>. The gate of field-effect transistor 28 is connected to a control line bCSLD1. The source of field-effect transistor 28 is grounded (connected to a power source Vss).

Control line bCSLD1 is connected to column decoder 7A via one inverter, and is supplied with an inversion signal of column select line CSLD1. The transistor 28 sets unselected bit lines BL to a ground voltage Vss. As a result, the bit line adjacent to a selected bit line BL is set to the ground voltage Vss, thereby enabling stable reading.

Each source line SL<m> is connected to only one of the four data lines DL2 via a column select transistor 25. The gate of column select transistor 25 is connected to a column select line CSLD2.

Column decoder 7B is connected to column select line CSLD2 via a buffer (two inverters). Column decoder 7B controls the on/off of column select transistor 27 via column select line CSLD2. When column select transistor 25 is switched on, a selected source line SL<m> is connected to data line DL2.

A field-effect transistor 29 is connected to each source line SL<m>. The drain of field-effect transistor 29 is connected to the source line SL<m>. The gate of field-effect transistor 29 is connected to a control line bCSLD2. The source of field-effect transistor 29 is grounded. Control line bCSLD2 is connected to column decoder 7B via one inverter. Control line bCSLD2 is supplied with an inversion signal of column select line CSLD2. Field-effect transistor 29 sets unselected source lines SL to a ground voltage VSS. As a result, the source line adjacent to a selected source line SL is set to the ground voltage VSS, thereby enabling stable reading.

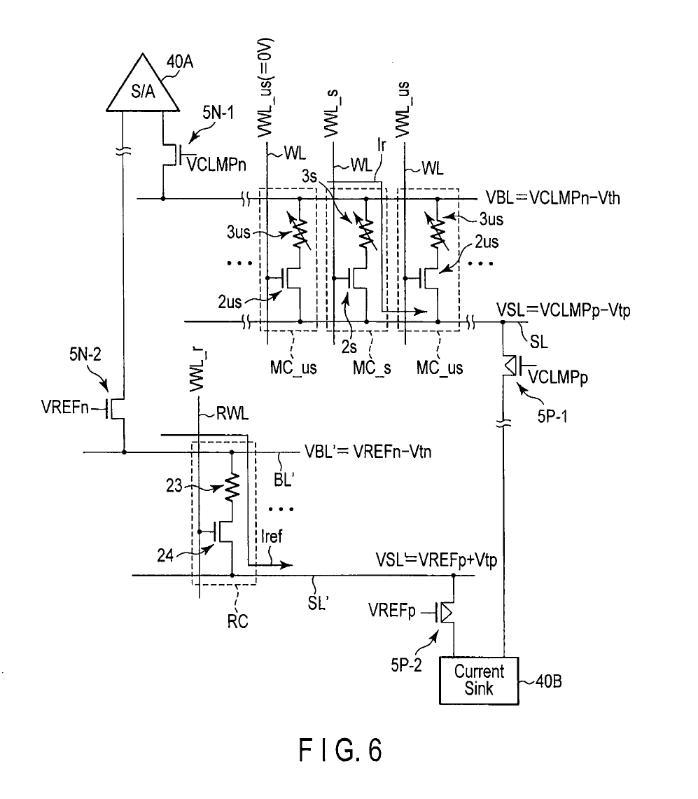

The connection of cells MC and RC, sense amplifier 40A, and the current sink 40B during a read is described with reference to FIG. 6.

FIG. 6 schematically shows the connection of the components when the memory cell MC connected to a bit line BL and a source line SL is read.

In the example shown in FIG. 6, a memory cell (selected cell) MC_s is selected, and other memory cells are not selected. The bit line BL and the source line SL to which the selected cell MC_s is connected are referred to as a selected bit line BL and a selected source line SL, respectively.

During a read, one end of the current path of n-channel field-effect transistor (e.g., n-channel MOS transistor) 5N-1 is connected to the selected bit line BL. The other end of the current path of n-channel MOS transistor 5N-1 is connected to one input terminal of sense amplifier 40A. A control voltage VCLMPn is applied to the gate of n-channel MOS transistor 5N-1. As a result of the application of control voltage VCLMPn, n-channel MOS transistor 5N-1 clamps the potential VBL of the bit line BL (to a substantially constant potential) during a read.

Threshold voltage Vtn (Vtn1) of n-channel MOS transistor 5N-1 is, for example, approximately 0.2 V (absolute value).

During a read, one end of the current path of p-channel field-effect transistor (e.g., p-channel MOS transistor) 5P-1 is connected to the selected source line SL. The other end of the current path of p-channel MOS transistor 5P-1 is connected to one input terminal of the current sink 40B. A control voltage VCLMPp is applied to the gate of p-channel MOS transistor 5P-1. As a result of the application of control voltage VCLMPp, p-channel MOS transistor 5P-1 clamps the potential VSL of the source line SL during a read.

Threshold voltage Vtp (Vtp1) of p-channel MOS transistor 5P-1 is, for example, approximately 0.2 V (absolute value).

Hereinafter, field-effect transistors 5N-1 and 5P-1 for clamping are referred to as clamp transistors 5N-1 and 5P-1. Control voltages VCLMPn and VCLMPp are referred to as clamp voltages VCLMPn and VCLMPp.

Thus, in the MRAM according to the present embodiment, in the path through which the read current Ir flows, n-channel clamp transistor 5N-1 which clamps the potential of the bit line BL is connected to the bit line BL to which the memory cells are connected, and p-channel clamp transistor 5P-1 which clamps the potential of the source line SL is connected to the source line SL that pairs with the bit line BL. The potential of the source line SL is set to be higher than the potential VWL_us of the word line WL to which unselected memory cells are connected.

In FIG. 6, for the simplification of the drawing, n-channel/p-channel clamp transistors 5N-1 and 5P-1 are directly connected to the bit line BL and the source line SL, respectively. However, if each of clamp transistors 5N-1 and 5P-1 is formed so that its current path (channel) is connected in series between the read circuit (the sense amplifier and the current sink) and the bit line/source line and so that the transistor can clamp the potential of the bit line/source line, each of clamp transistors 5N-1 and 5P-1 may be connected to the read circuit and the bit line/source line via data line DL1 or DL2 and other components.

When a read method that uses the reference cell is used, the reference cell RC is electrically connected to the read circuits (the sense amplifier and the current sink) via field-effect transistors 5N-2 and 5P-2.

One end of the current path of n-channel MOS transistor 5N-2 is connected to a bit line BL′ to which the reference cell RC is connected. The other end of the current path of n-channel MOS transistor 5N-2 is connected to the other input terminal of sense amplifier 40A.

One end of the current path of p-channel MOS transistor 5P-2 is connected to a source line SL′ to which the reference cell RC is connected. The other end of the current path of p-channel MOS transistor 5P-2 is connected to the current sink 40B.

Hereinafter, for a clear explanation, the bit line BL′ to which the reference cell RC is connected is referred to as a reference bit line BL′, and the source line SL′ to which the reference cell RC is connected is referred to as a reference source line SL′. The MOS 15 transistors 5N-2 and 5P-2 may also be connected to read circuits 40A and 40B and the reference bit line BL′/reference source line SL′ via other components such as data lines DL1 and DL2. As shown in FIG. 3, a memory cell is connected between the reference bit line BL′ and the reference source line SL′.

A control signal VREFn (V3) is applied to the gate of n-channel MOS transistor 5N-2. As a result of the application of control signal VREFn, n-channel MOS transistor 5N-2 clamps the potential VBL′ of the reference bit line BL′. Threshold voltage Vtn2 of n-channel MOS transistor 5N-2 is, for example, as high as threshold voltage Vtn of n-channel clamp transistor 5N-1.

A control signal VREFp (V4) is applied to the gate of p-channel MOS transistor 5P-2. As a result of the application of control signal VREFp, p-channel MOS transistor 5P-2 clamps the potential VSL′ of the reference source line SL′. Threshold voltage Vtp2 of p-channel MOS transistor 5P-2 is, for example, as high as threshold voltage Vtp of p-channel clamp transistor 5P-1.

Transistors 5N-2 and 5P-2 connected to the reference bit line BL′ and the reference source line SL′ are substantially similar in function to clamp transistors 5N-1 and 5P-1, and clamp the potentials VBL′ and VSL′ of the reference bit line BL′ and the reference source line SL′ during reading.

Control voltages VREFn and VREFp for the reference bit line BL′ and the reference source line SL′ are different from, for example, clamp voltages VCLMPn and VCLMPp. Control voltages VREFn and VREFp different from clamp voltages VCLMPn and VCLMPp are applied to the MOS transistors 5N-2 and 5P-2 respectively connected to the reference bit line BL′ and the reference source line SL′ to control the potential of the reference bit line BL′ and the potential of the reference source line SL′. The potential of the reference bit line BL′ and the potential of the reference source line SL′ are different from the potential of the bit line BL and the potential of the source line SL, respectively.

During a read, instead of supplying the reference current to sense amplifier 40A via the reference cell RC, a current generated by the constant current source (or the constant voltage source) and having a constant magnitude may be directly supplied to sense amplifier 40A. In this case, the other input terminal of sense amplifier 40A is not connected to the reference cell but is connected to the constant current source.

In a read, a selected word line potential VWL_s of approximately 1.2 V is applied to the selected word line WL. The selected word line potential VWL_s is applied to the gate of cell transistor 2s in the selected cell MC_s, and cell transistor 2s is switched on.

On the other hand, a potential of 0V, for example, is applied to unselected word lines as an unselected word line potential VWL_us. Cell transistor 2us in the unselected cell MC_us is kept off.

If cell transistor 2us in the unselected cell MC_us is off, the unselected word line potential VWL_us may be higher than zero. However, in the present embodiment, the unselected word line potential VWL_us is lower than the source line potential VSL.

In a read, the potential VBL of the selected bit line BL is set to approximately VCLMPn−Vtn under potential control by clamp transistor 5N-1. The potential VSL of the selected source line SL is set to approximately VCLMPp+Vtp under potential control by clamp transistor 5P-1.

Clamp voltages VCLMPn and VCLMPp are adjusted so that potential VBL of the selected bit line BL is higher than potential VSL of the selected source line SL. For example, clamp voltage VCLMPn for the selected bit line BL is set to approximately 0.85 V (absolute value), and clamp voltage VCLMPp for the selected source line SL is set to approximately 0.35 V (absolute value). In this case, the bit line potential VBL is approximately 0.65 V, and the source line potential VSL is approximately 0.55 V.

Therefore, the read current Ir flows toward the selected source line from the selected bit line via the selected cell MC_s. Clamp voltages VCLMPn and VCLMPp are not limited to the above-mentioned values. Threshold voltages Vtn and Vtp are not limited to the above-mentioned values either. For example, in a read, the clamp transistors connected to the unselected bit lines and the unselected source lines are off.

Moreover, in a read, a selected word line potential VWL_r of approximately 1.2 V, for example, is applied to the reference word line RWL. The selected word line potential VWL_r is applied to the gate of cell transistor 24 in the reference cell RC, and cell transistor 24 is switched on.

The transistors in the memory cells connected to the reference bit line BL′ and the reference source line SL′ are switched off. That is, a word line potential of zero is applied to the gate of the cell transistor for the memory cells connected to the reference bit line BL′ and the reference source line SL′.

The potential VBL′ of the reference bit line BL′ is set to approximately VREFn−Vtn under potential control by field-effect transistor 5N-2. The potential VSL′ of the reference source line SL′ is set to approximately VREFp+Vtn under potential control by field-effect transistor 5P-2. The potential VBL′ of the reference bit line BL′ is higher than the potential VSL′ of the reference source line SL′. Therefore, a standard current (reference current) Iref flowing through the reference cell RC flows toward the reference source line from the reference bit line.

The reference current Iref is adjusted by control voltages VREFn and VREFp so that it will be between the read current flowing when the MTJ element is in the high-resistance state and that flowing when the MTJ element is in the low-resistance state.

The read current Ir and the reference current Iref are set to such a degree that does not change the resistance of the resistance-change memory element. In the MRAM, the read current Ir and the reference current Iref are lower than the magnetization inversion threshold of the recording layer.

In a read, the read current Ir flows from sense amplifier 40A to the current sink 40B via the selected cell MC_s. The reference current Iref flows from sense amplifier 40A to the current sink 40B via the reference cell RC.

The current sink 40B takes in the read current Ir and the reference current Iref.

Sense amplifier 40A compares the read current Ir with the reference current Iref, and thereby detects the resistance of the MTJ element 3s in the selected cell MC_s. The data stored in the MTJ element is determined by the resistance of the detected MTJ element 3s.

The current Iref flowing through the reference cell RC is used as a standard current for detecting the resistance during a read (for determining data), so that the influence of an interconnect delay on the operation can be reduced, and the read can be faster than when a constant current (or potential) is used as a standard current to read data.

In this way, during the read, cell transistor 2s in the selected cell MC_s is switched on, and the read current Ir flows through the selected cell MC_s. At the same time, cell transistor 2_us of the unselected cell MC_us is off, and the source line potential VSL is higher than the potential VWL_us of the unselected word line WL.

That is, in the MRAM according to the present embodiment, when the selected cell MC_s is read, the source voltage of cell transistor 2_us of the unselected cell MC_us is higher than the gate voltage of cell transistor 2_us of the unselected cell MC_us. In this case, a reverse bias is applied across the channel region (e.g., a p-type semiconductor layer) and the source (e.g., an n-type semiconductor layer) of n-channel cell transistor 2_us.

Therefore, the leakage current from cell transistor 2us in the unselected cell MC_us is reduced. The leakage current from the cell transistor is attributed to the adverse-effect of element miniaturization, for example, a short channel-effect.

In the memory cell (unselected cell) connected to the reference bit line BL′ and the reference source line SL′, the gate voltage (word line potential) of the cell transistor is also higher than the source voltage. Thus, a leakage current from the memory cell between the reference bit line BL′ and the reference source line SL′ is also reduced.

Accordingly, in the resistance-change memory according to the first embodiment, a leakage current from the unselected cell during a read can be reduced, and noise due to the leakage current in data reading can be inhibited.

As described above, according to the first embodiment, read accuracy can be improved.

(b) Operation

The operation of the resistance-change memory (e.g., MRAM) according to the first embodiment is described with reference to FIG. 2 to FIG. 6. Here, an MRAM read according to the present embodiment is described.

During a read, a read command and an address of a memory cell to be read are input to an MRAM chip from the outside.

The row decoders 8-1 and 8-2 in FIG. 2 select one of the word lines in accordance with the input address signal. Column decoders 7A-1, 7A-2, 7B-1, and 7B-2 in FIG. 2 controls the on/off of column select transistors 25 and 27 in accordance with the input address. Column decoders 7A-1, 7A-2, 7B-1, and 7B-2 select one of the bit lines and select one of the source lines.

In the read method that uses the reference cell RC, when the memory cell MC of cell array 1-1 is selected in a read, the reference cell RC of cell array 1-2 is selected. In contrast, when the memory cell MC of cell array 1-2 is selected, the reference cell RC of cell array 1-1 is selected.

For example, as shown in FIG. 2, two memory cells MC1 and MC2 connected to the same selected word lines in cell array 1-1 can be simultaneously read. Memory cells MC1 and MC2 belong to different columns, and are connected to different bit lines BL and source lines SL. When memory cells MC1 and MC2 in cell array 1-1 are simultaneously selected, two reference cells RC1 and RC2 in cell array 1-2 are simultaneously selected. Memory cell MC1 and memory cell MC2 are selected by the common word line WL. The two reference cells RC1 and RC2 belong to different columns, and are connected to different bit lines BL and source lines SL. The two reference cells RC1 and RC2 are connected to the common reference word line RWL.

Sense amplifier 40A-1 is connected to memory cell MC1 and reference cell RC1 via data line DL1. Current sink 40B-1 is connected to memory cell MC1 and reference cell RC1 via data line DL2. Sense amplifier 40A-2 is connected to memory cell MC2 and reference cell RC2 via data line DL1. Current sink 40B-2 is connected to memory cell MC2 and reference cell RC2 via data line DL2.

Sense amplifier 40A-1 compares the read current (or a potential based on the current) flowing to current sink 40B-1 via memory cell MC1 with the reference current (or a potential based on the current) flowing to current sink 40B-1 from sense amplifier 40A-1 via reference cell RC1. Thus, sense amplifier 40A-1 detects the resistance of the resistance-change memory element (MTJ element) in memory cell MC1. The data stored in the MTJ element is determined by the detected resistance. Sense amplifier 40A-2 compares a read current from memory cell MC2 with a reference current from reference cell RC2 in the same cycle as the read of memory cell MC1, such that the data in memory cell MC2 is determined.

As described above, in the MRAM according to the present embodiment, the two memory cells MC1 and MC2 can be simultaneously read.

The relation between the potentials of the bit line and the source line in reading a selected cell is described with reference to FIG. 6.

As shown in FIG. 6, a selected word line potential VWL_s of approximately 1.2 V is applied to the selected word line WL so that cell transistor 2s in the selected cell MC_s will be switched on. An unselected word line potential VWL_us of zero, for example, is applied to unselected word lines.

During a read, clamp transistor 5N-1 controls the potential VBL of the selected bit line BL. Clamp voltage VCLMPn is applied to the gate of clamp transistor 5N-1. The potential VBL of the selected bit line BL is clamped by n-channel clamp transistor 5N-1 in accordance with the clamp voltage VCLMPn. The potential VBL of the selected bit line BL is represented by VCLMPn−Vtn when the threshold voltage of n-channel clamp transistor 5N-1 is represented by Vtn.

Clamp transistor 5P-1 controls the potential VSL of the selected source line SL. Clamp voltage VCLMPp is applied to the gate of clamp transistor 5P-1. The potential VSL of the selected source line SL is clamped by p-channel clamp transistor 5P-1 in accordance with the clamp voltage VCLMPp. The potential VSL of the selected source line SL is represented by VCLMPp+Vtp when the threshold voltage of p-channel clamp transistor 5P-1 is represented by Vtp.

Here, the selected bit line potential VBL is approximately 0.65 V when clamp voltage VCLMPn is approximately 0.85 V and threshold voltage Vtn is approximately 0.2 V. The selected source line potential VSL is approximately 0.55 V when clamp voltage VCLMPp is approximately 0.35 V and threshold voltage Vtp is approximately 0.2 V. Clamp voltages VCLMPn and VCLMPp are not limited to the above-mentioned values. Threshold voltages Vtn and Vtp of clamp transistors 5N and 5P correspond to the characteristics of transistors 5N and 5P to be formed.

A potential VWL_r of approximately 1.2 V, for example, is applied to the reference word line RWL to which the reference cell RC is connected so that cell transistor 24 in the reference cell RC will be switched on. In the memory cells connected between the reference bit line BL′ and the reference source line SL′, a word line potential (unselected word line potential) of zero is applied to the gates of the cell transistors in these memory cells. Therefore, the cell transistors in the memory cells between the reference bit line and the reference source line are off.

The potential VBL′ of the reference bit line BL′ to which the reference cell RC is connected is controlled by n-channel MOS transistor 5N-2. Control voltage VREFn is applied to the gate of n-channel MOS transistor 5N-2, and the potential VBL′ of the reference bit line BL′ is clamped in accordance with the control voltage VREFn. The potential VSL′ of the reference source line SL′ to which the reference cell RC is connected is controlled by p-channel MOS transistor 5P-2. Control voltage VREFp is applied to the gate of p-channel MOS transistor 5P-2, and the potential VSL′ of the reference source line SL′ is clamped in accordance with the control voltage VREFp.

The potential VBL′ of the reference bit line BL′ is represented by, for example, VREFn−Vtn when the threshold voltage of n-channel MOS transistor 5N-2 is represented by Vtn. The potential VSL′ of the reference source line SL′ is represented by, for example, VREFp+Vtp when the threshold voltage of p-channel MOS transistor 5P-2 is represented by Vtp. Control voltages VREFn and VREFp may be the same as or different from clamp voltages VCLMPn and VCLMPp. However, the potential VBL′ of the reference bit line BL′ is adjusted to be higher than the potential VSL′ of the reference source line SL′.

The reference current Iref is adjusted by control voltages VREFn and VREFp so that it will be between the read current flowing when the MTJ element is in the high-resistance and the read current flowing when the MTJ element is in the low-resistance.

The potential difference between the selected bit line BL and the selected source line SL is approximately 0.1 V. As a result of this potential difference, the read current Ir flows through the MTJ element 3s in the selected cell MC_s via cell transistor 2s that is on. As a result of the potential difference between the reference bit line BL′ and the reference source line SL′, the reference current Iref flows through the resistive element 23 in the reference cell RC via cell transistor 24 that is on. The read current Ir and the reference current Iref are lower than the write current Iw.

As described above, sense amplifier 40A compares the read current Ir with the reference current Iref. The resistance of the MTJ element 3s in the selected cell MC_s is thereby detected, and the data stored in the MTJ element 3s is read.

Here, in accordance with the relation between the unselected word line potential VWL_us and the selected source line potential VSL, 0 V is applied to the gate of cell transistor 2us in the unselected cell MC_us, and a voltage of 0.55 V is applied to the source of cell transistor 2us. That is, a reverse bias is applied across the channel region and the source (pn junction) in n-channel cell transistor 2us. Thus, the leakage current of the unselected cell 2us is reduced, and noise resulting from the leakage current of the unselected cells during a read is reduced.

In the cell transistor of the memory cell connected between the reference bit line BL′ and the reference source line SL′, the potential VSL′ of the reference source line SL′ is also higher than the word line potential (unselected word line potential). Thus, the leakage current of the cell transistor in the memory cell connected between the reference bit line BL′ and the reference source line SL′ is reduced.

In the present embodiment, the current Iref flowing through the reference cell RC is supplied to sense amplifier 40A as a standard current. However, during a read, a constant current from the constant current source (or the constant voltage source) may be directly supplied to sense amplifier 40A as a standard current without the reference cell RC connected to sense amplifier 40A.

As described above, the operation of the resistance-change memory according to the first embodiment enables improved read accuracy.

### (2) Second Embodiment

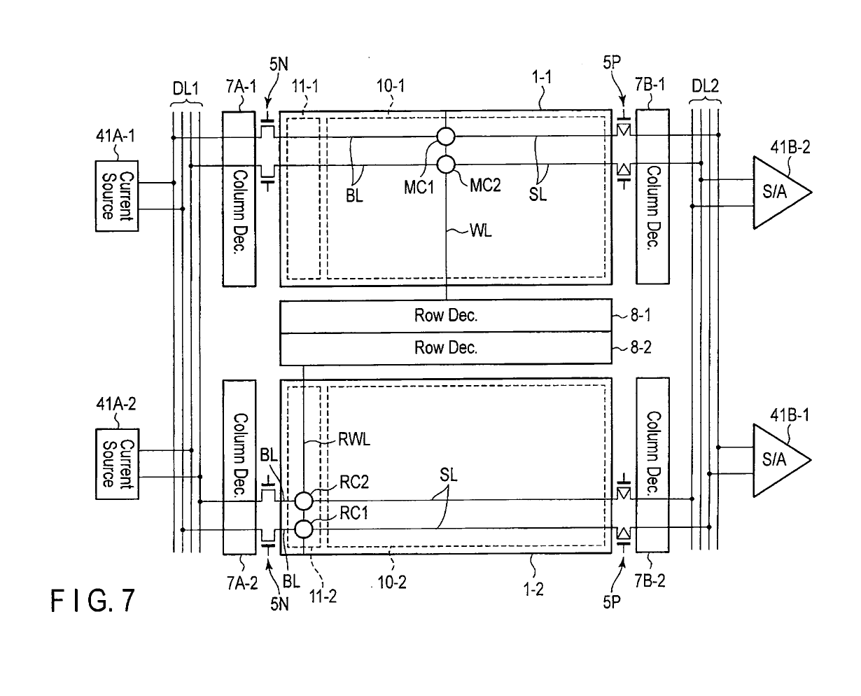

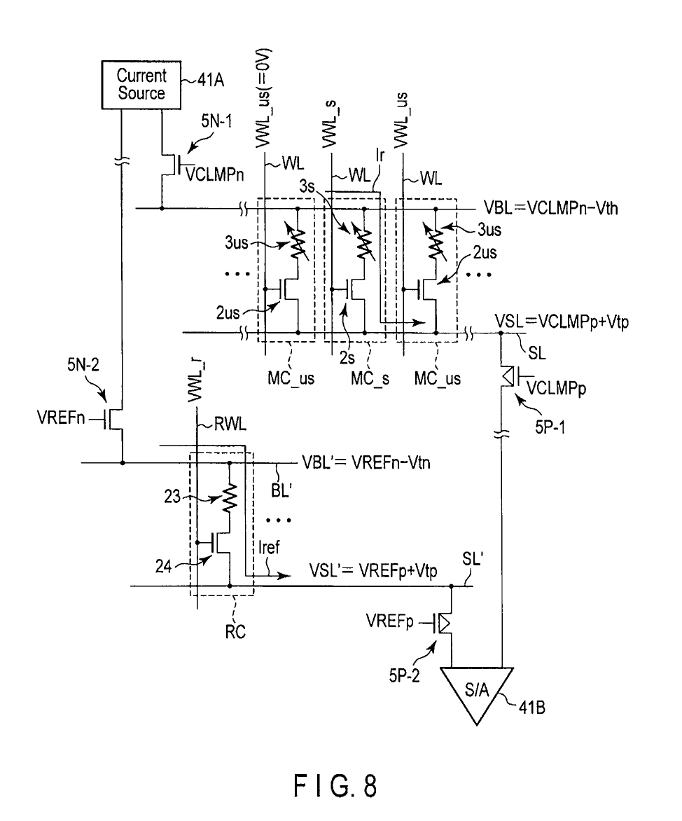

A resistance-change memory according to the second embodiment is described with reference to FIG. 7 and FIG. 8. The difference between the second embodiment and the first embodiment is mainly described below, and repeated explanations are given when necessary.

The circuit configuration of the resistance-change memory (e.g., MRAM) according to the second embodiment is described with reference to FIG. 7 and FIG. 8.

As shown in FIG. 7, current sources 41A-1 and 41A-2 and sense amplifiers 41B-1 and 41B-2 may be used as read circuits 4A, 4B.

Current sources 41A-1 and 41A-2 are connected to data lines DL1. Current sources 41A-1 and 41A-2 output currents to data lines DL1 and bit lines BL.

Sense amplifiers 41B-1 and 41B-2 are connected to data lines DL2. Sense amplifiers 41B-1 and 41B-2 compare a read current Ir flowing through a selected cell with a standard current (reference current).

During a read, for example, current source 41A-1 is connected to a memory cell MC1 in a cell array 1-1 and a reference cell RC1 in a cell array 1-2 via data line DL1. Current source 41A-2 is connected to memory cell MC2 in cell array 1-1 and a reference cell RC2 in cell array 1-2 via data line DL1.

Sense amplifier 41B-1 is connected to memory cell MC1 in cell array 1-1 and reference cell RC1 in cell array 1-2 via data line DL2. Sense amplifier 41B-2 is connected to memory cell MC2 in cell array 1-1 and reference cell RC2 in cell array 1-2 via data line DL2.

Thus, as in the first embodiment, the two memory cells MC1 and MC2 can be simultaneously read in one read cycle.

The connection between current source/sense amplifier 41A-1, 41A-2, 41B-1 or 41B-2 and the memory cell/reference cell in cell array 1-1 or 1-2 can be modified under the control of column decoder 7A-1, 7A-2, 7B-1, or 7B-2 in accordance with a command and an address that are input.

In the MRAM according to the second embodiment, current sources 41A-1 and 41A-2 function as high-potential-side read circuits 4A, and sense amplifiers 41B-1 and 41B-2 function as low-potential-side read circuits 4B.

In the present embodiment, transistors 5N and 5P which clamp the potentials of a selected bit line and a selected source line during a read are provided, as in the first embodiment.

As shown in FIG. 8, one end of the current path of an n-channel clamp transistor 5N-1 is connected to the current source 41A. The other end of the current path of n-channel clamp transistor 5N-1 is connected to the bit line BL. One end of the current path of a p-channel clamp transistor 5P-1 is connected to one input terminal of sense amplifier 41B. The other end of the current path of p-channel clamp transistor 5P-1 is connected to a source line SL.

As described above, in the second embodiment as well, in the path where the read current Ir flows, the current path (channel region) of n-channel clamp transistor 5N-1 which clamps the potential of the bit line BL is connected in series to the bit line BL to which the memory cells are connected, and the current path (channel region) of p-channel clamp transistor 5P-1 which clamps the potential of the source line SL is connected to the source line SL that pairs with the bit line BL.

One end of the current path of an n-channel MOS transistor 5N-2 is connected to the current source 41A. The other end of the current path of n-channel MOS transistor 5N-2 is connected to a reference bit line BL′. One end of the current path of a p-channel MOS transistor 5P-2 is connected to the other input terminal of sense amplifier 41B. The other end of the current path of p-channel MOS transistor 5P-2 is connected to a reference source line SL′.

During a read, the read current Ir flows from the current source 41A to sense amplifier 41B via a selected cell MC_s. A reference current Iref flows from the current source 41A to sense amplifier 41B via a reference cell RC.

Sense amplifier 41B then compares the supplied read current Ir with the reference current Iref. The resistance of the MTJ element 3s in the selected cell MC_s is thereby detected, and the data stored in the MTJ element 3s is determined.

In the MRAM according to the second embodiment, the selected bit line potential VBL is controlled by clamp voltages VCLMPn and VCLMPp to be higher than the selected source line potential VSL, as in the first embodiment.

A selected word line potential VWL_s is higher than the selected bit line potential VBL and higher than the selected source line potential VSL. The selected source line potential VSL is higher than the unselected word line potential VWL_us.

Accordingly, in the present embodiment as well, the gate voltage of a cell transistor 2_us in an unselected cell MC_us is lower than the source voltage of cell transistor 2_us. Therefore, a reverse bias is applied across the channel region and the source region (pn junction) of cell transistor 2us, and a leakage current from the unselected cell MC_us is reduced. As a result, noise resulting from the leakage current is reduced during a read.

Consequently, the resistance-change memory according to the second embodiment enables improved read accuracy, as in the resistance-change memory according to the first embodiment.

### (3) Modification

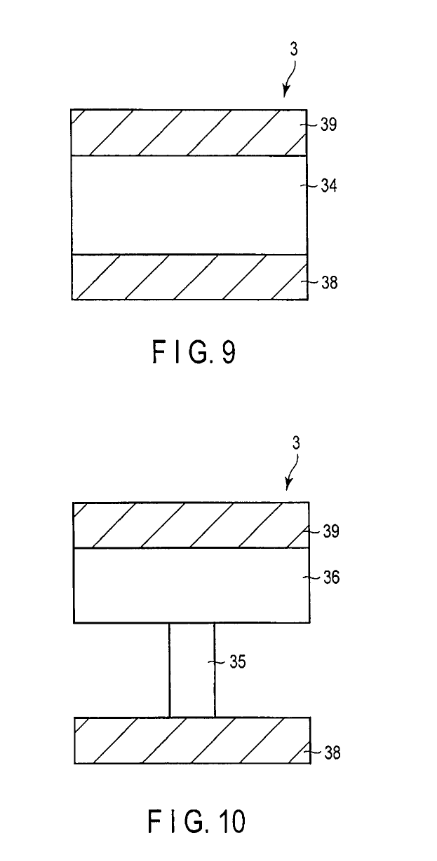

A modification of the resistance-change memory according to the first and second embodiments is described with reference to FIG. 9 and FIG. 10.

In the first and second embodiments, the MRAM is shown as an example of the resistance-change memory. It should, however, be understood that the resistance-change memory according to the embodiments may be a resistance-change memory other than MRAM, such as resistive RAM (ReRAM) and phase-change RAM (PCRAM).

For example, in a ReRAM, a variable resistance element is used as a memory element. The memory element used in the ReRAM is reversibly changed in resistance by energy such as a voltage, a current, or heat, and maintains the changed resistance in a nonvolatile manner.

FIG. 9 shows a structure example of the resistance-change memory element (variable resistance element) 3 used in the ReRAM.

The variable resistance element 3 as the resistance-change memory element 3 includes a lower electrode 38, an upper electrode 39, and a resistance-change film (recording layer) 34 intervening between these electrodes 38, 39.

The resistance-change film 34 is made of a transition metal oxide such as a perovskite-type metal oxide or a binary metal oxide. The perovskite-type metal oxide includes, for example, PCMO (Pr_{0.7}Ca_{0.3}MnO₃), Nb-added SrTi(Zr)O₃, and Cr-added SrTi(Zr)O₃. The binary metal oxide includes, for example, NiO, TiO₂ and Cu₂O.

For example, the resistance of the resistance-change film 34 changes with the production or disappearance of a micro current path (filament) in the film 34, or the movement of ions that constitute the film 34.

The variable resistance element 3 includes an element of an operation mode called a bipolar type and an element of an operation mode called a unipolar type.

The bipolar type element 3 changes its resistance in accordance with the change of the polarity of a voltage applied thereto. The unipolar type element 3 changes its resistance in accordance with the change of one or both of the absolute value and pulse width of a voltage applied thereto. Thus, the variable resistance element 3 as the resistance-change memory element is set to a low-resistance state or a high-resistance state by the control of the applied voltage. Whether the variable resistance element 3 is the bipolar type or the unipolar type depends on the material of the resistance-change film 34 or on the combination of the materials of the resistance-change film 34 and the electrodes 38 and 39.

The low-resistance state and the high-resistance state of the variable resistance element 3 are matched with binary 0 and binary 1, respectively, such that the variable resistance element 3 as the resistance-change memory element can store one-bit data.

Writing to the variable resistance element 3 as the resistance-change memory element 3, that is, changing the resistance of the variable resistance element 3 is called a reset operation/set operation. When the variable resistance element 3 is brought into the high-resistance state, a reset voltage is applied to the element 3. When the variable resistance element 3 is brought into the low-resistance state, a set voltage is applied to the element 3.

In order to read, a read voltage sufficiently lower than the set voltage and the reset voltage is applied to the variable resistance element 3, and a current flowing through the variable resistance element 3 at the same time is detected.

In the PCRAM, a phase-change element is used as the resistance-change memory element 3. The phase of the phase-change element 3 reversibly changes from a crystalline state to an amorphous (noncrystalline) state or from an amorphous state to a crystalline state due to externally applied energy. As a result of the change in the phase of the film, the resistance (impedance) of the phase-change element changes. The condition in which the crystalline phase of the phase-change element has changed is retained in a nonvolatile manner until energy necessary to change the crystalline phase is provided.

FIG. 10 shows a structure example of the memory element (phase-change element) used in the PCRAM. The phase-change element 3 as a resistance-change memory element includes a lower electrode 38, a heater layer 35, a phase-change film (storage layer) 36, and an upper electrode 39 that are stacked.

The phase-change film 36 is made of a phase-change material, and is changed into a crystalline state or an amorphous state by heat produced during a write. The material of the phase-change film 36 includes chalcogen compounds such as Ge—Sb—Te, In—Sb—Te, Ag—In—Sb—Te, and Ge—Sn—Te. These materials are preferable in ensuring high-speed switching performance, repeated recording stability, and high reliability.

The heater layer 35 is in contact with the bottom surface of the phase-change film 36. The area of contact of the heater layer 35 with the phase-change film 36 is preferably smaller than the area of the bottom surface of the phase-change film 36. The purpose is to decrease a write current or voltage by reducing the contact part between the heater layer 35 and the phase-change film 36 to reduce a heated part. The heater layer 35 is made of a conducting material, and is preferably made of, for example, a material selected from the group including TiN, TiAlN, TiBN, TiSiN, TaN, TaAlN, TaBN, TaSiN, WN, WAIN, WBN, WSiN, ZrN, ZrAlN, ZrBN, ZrSiN, MoN, Al, Al—Cu, Al—Cu—Si, WSi, Ti, Ti—W, and Cu. Moreover, the heater layer 35 may be made of the same material as the lower electrode 38.

The area of the lower electrode 38 is larger than the area of the heater layer 35. The upper electrode 39 has, for example, the same planar shape as the phase-change film 36. The material of the lower electrode 38 and the upper electrode 39 includes a high melting point metal such as Ta, Mo, or W.

The heating temperature and heating time of the phase-change film 36 are changed by controlling the magnitude and width of a current pulse applied to this phase-change film 36, and the phase-change film 36 changes into the crystalline state or amorphous state.

The crystalline state of the phase-change film 36 is changed to write into the variable resistance element 3 as the resistance-change memory element.

In a write, a voltage or a current is applied across the lower electrode 38 and the upper electrode 39, and a current is passed to the upper electrode 39 from the lower electrode 38 via the phase-change film 36 and the heater layer 35. If the phase-change film 36 is heated to near the melting point, the phase-change film 36 changes into an amorphous phase (high-resistance phase). The phase-change film 36 maintains the amorphous state even when the application of the voltage or current is stopped. On the other hand, a voltage or a current is applied across the lower electrode 38 and the upper electrode 39. If the phase-change film 36 is heated to near a temperature suitable for crystallization, the phase-change film 36 changes into a crystalline phase (low-resistance phase). The phase-change film 36 maintains the crystalline state even when the application of the voltage or current is stopped. When the phase-change film 36 is changed into the crystalline state, the set magnitude of the current pulse applied to the phase-change film 36 is lower and the set width of the current pulse is greater than, for example, when the phase-change film 36 is changed into the amorphous state.

Whether the phase-change film 36 is in the crystalline phase or the amorphous phase can be known by applying, across the lower electrode 38 and the upper electrode 39, such a low voltage or low current that does not cause the phase-change film 36 to be crystalline or amorphous and reading the current flowing through the element 3.

Thus, the low-resistance state (crystalline state) and the high-resistance state (amorphous state) of the phase-change element 3 are matched with binary 0 and binary 1, respectively, such that one-bit data can be read from the resistance-change memory element 3 of the PCRAM.

As described above, in the resistance-change memory according to the present embodiment, the variable resistance element or the phase-change element may be used as the resistance-change memory element 3 instead of the magnetoresistive-effect element (MTJ element) 3.

When the memory cell includes the resistance-change memory element other than the magnetoresistive-effect element (MTJ element), the read accuracy can also be improved as described in the first and second embodiments.

[Addition]

In the resistance-change memory according to the embodiments, the memory cell has one cell transistor connected to one resistance-change memory element. The embodiments are not limited thereto. Two or more cell transistors may be provided in the memory cell so that the current paths of the transistors are connected in series between the bit line and the source line. Accordingly, two source lines may be connected to the memory cell, and the source lines may be connected to the current paths of the two transistors, respectively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A resistance-change memory comprising:
a bit line;
a source line;
word lines;
memory cells connected between the bit line and the source line, each of the memory cells including a memory element in which a resistance is correlated with data to be stored, and a first cell transistor having a gate connected to the word line;
an n-channel first transistor, the first transistor having a first gate to which a first control voltage is applied, and a first current path connected to the bit line; and
a p-channel second transistor, the second transistor having a second gate to which a second control voltage is applied, and a second current path connected to the source line,
wherein when a selected memory cell is read,
the potential of the bit line is controlled by the first control voltage, and the potential of the source line is controlled by the second control voltage.

2. The resistance-change memory according to claim 1, wherein
the potential of the bit line is higher than the potential of the source line,
the potential of the word line to which the selected memory cell is connected is higher than the potential of the bit line, and
the potential of the word line to which an unselected memory cell is connected is lower than the potential of the source line.

3. The resistance-change memory according to claim 2, wherein
the potential of the word line to which the selected memory cell is connected is higher than the potential of the bit line.

4. The resistance-change memory according to claim 1, wherein
the potential of the bit line in the read is represented by V1−Vtn when the first control voltage is represented by V1 and the threshold voltage of the first transistor is represented by Vtn, and
the potential of the source line in the read is represented by V2+Vtp when the second control voltage is represented by V2 and the threshold voltage of the second transistor is represented by Vtp.

5. The resistance-change memory according to claim 1, wherein
the first and second transistors comprise source followers.

6. The resistance-change memory according to claim 1, further comprising:
a sense amplifier having a first input terminal which is connected to the bit line via the first transistor; and
a sink circuit connected to the source line via the second transistor.

7. The resistance-change memory according to claim 6, further comprising:
a reference cell which includes a resistive element and a second cell transistor and which is connected to a second input terminal of the sense amplifier,
wherein in the read, a current flowing through the reference cell in an on-state is supplied to the sense amplifier as a standard current to detect the resistance of a resistance-change memory element in the selected memory cell.

8. The resistance-change memory according to claim 7, wherein
the memory cell is provided in a first memory cell array, and the reference cell is provided in a second memory cell array different from the first memory cell array.

9. The resistance-change memory according to claim 1, further comprising:
a source circuit connected to the bit line via the first transistor; and
a sense amplifier having a first input terminal which is connected to the source line via the second transistor.

10. The resistance-change memory according to claim 9, further comprising:
a reference cell which includes a resistive element and a second cell transistor and which is connected to a second input terminal of the sense amplifier,
wherein in the read, a current flowing through the reference cell in an on-state is supplied to the sense amplifier as a standard current to detect the resistance of a resistance-change memory element in the selected memory cell.

11. The resistance-change memory according to claim 10, wherein
the memory cell is provided in a first memory cell array, and the reference cell is provided in a second memory cell array different from the first memory cell array.

12. The resistance-change memory according to claim 1, wherein
the memory element is an element selected from the group including a magnetoresistive-effect element, a variable resistance element, and a phase-change element.

13. A resistance-change memory comprising:
first and second bit lines;
first and second source lines;
word lines;
a first reference word line;
memory cells connected between the first bit line and the first source line, each of the memory cells including a memory element in which a resistance is correlated with data to be stored, and a first cell transistor having a gate connected to the word line;
a reference cell connected between the second bit line and the second source line, the reference cell including a resistive element, and a second cell transistor having a gate connected to the reference word line;
an n-channel first transistor, the first transistor having a first gate to which a first control voltage is applied, and a first current path which has one end connected to the first bit line;
a p-channel second transistor, the second transistor having a second gate to which a second control voltage is applied, and a second current path which has one end connected to the first source line;
an n-channel third transistor, the third transistor having a third gate to which a third control voltage is applied, and a third current path which has one end connected to the second bit line; and
a p-channel fourth transistor, the fourth transistor having a fourth gate to which a fourth control voltage is applied, and a fourth current path which has one end connected to the second source line,
wherein when a selected memory cell is read,
the potential of the first bit line is controlled by the first control voltage, and the potential of the first source line is controlled by the second control voltage, and
the potential of the second bit line is controlled by the third control voltage, and the potential of the second source line is controlled by the fourth control voltage.

14. The resistance-change memory according to claim 13, wherein
the potential of the first bit line is higher than the potential of the first source line,
the potential of the word line to which the selected memory cell is connected is higher than the potential of the first bit line, and
the potential of the word line to which an unselected memory cell is connected is lower than the potential of the first source line.

15. The resistance-change memory according to claim 14, wherein
the potential of the second bit line is higher than the potential of the second source line, and is different from the potential of the first bit line.

16. The resistance-change memory according to claim 13, wherein
the potential of the first bit line in the read is represented by V1−Vtn1 when the first control voltage is represented by V1 and the threshold voltage of the first transistor is represented by Vtn1,
the potential of the first source line in the read is represented by V2+Vtp1 when the second control voltage is represented by V2 and the threshold voltage of the second transistor is represented by Vtp1,
the potential of the second bit line in the read is represented by V3−Vtn2 when the third control voltage is represented by V3 and the threshold voltage of the third transistor is represented by Vtn2, and
the potential of the second source line in the read is represented by V4+Vtp2 when the fourth control voltage is represented by V4 and the threshold voltage of the fourth transistor is represented by Vtp2.

17. The resistance-change memory according to claim 13, wherein
the first to fourth transistors comprise source followers.

18. The resistance-change memory according to claim 13, further comprising:
a sense amplifier including a first input terminal which is connected to the first bit line via the first transistor, and a second input terminal which is connected to the second bit line via the third transistor; and
a sink circuit to which a current from the memory cell is input via the second transistor and to which a current from the reference cell is input via the fourth transistor.

19. The resistance-change memory according to claim 13, further comprising:
a source circuit configured to produce a current to be supplied to the first and second bit lines, the source circuit having a first output terminal connected to the first bit line via the first transistor, and a second output terminal connected to the third bit line via the third transistor; and
a sense amplifier including a first input terminal connected to the first source line via the second transistor, and a second input terminal connected to the second bit line via the fourth transistor.

20. The resistance-change memory according to claim 13, wherein
in the read, a current from the second bit line flows through the reference cell in an on-state, and a standard current to detect the resistance of a memory element in the selected memory cell is produced, and
the standard current is set to an intermediate value between the current flowing through the memory element in a high-resistance state and the current flowing through the memory element in a low-resistance state.
